(19) United States
(12) Patent Application Publication
(10) Pub. No.: US 2023/0182232 A1
(43) Pub. Date: Jun. 15, 2023

(54) MANUFACTURING METHOD OF CONDUCTIVE PATTERN

(71) Applicant: MITUTOYO CORPORATION, Kawasaki-Kanagawa (JP)

(72) Inventor: Kosaku Miyake, Kawasaki (JP)

(21) Appl. No.: 18/075,979

(22) Filed: Dec. 6, 2022

(30) Foreign Application Priority Data
Dec. 10, 2021 (JP) 2021-201116

(51) Int. Cl. B23K 26/0622; B23K 26/364

(52) U.S. Cl. CPC B23K 26/0624; B23K 26/364

(57) ABSTRACT

A manufacturing method of a conductor pattern includes, preparing a substrate provided with a conductor on one main surface thereof, forming an outline of the conductor pattern on the conductor with a short-pulse laser, and removing at least a part of the conductor other than the conductor pattern by etching.

### CROSS-REFERENCE TO RELATED APPLICATION

This application is based upon and claims the benefit of priority of the prior Japanese Patent Application No. 2021-201116 filed on Dec. 10, 2021, the entire contents of which are incorporated herein by reference.

### FIELD

A certain aspect of embodiments described herein relates to a manufacturing method of a conductive pattern.

### BACKGROUND

A scale is disclosed for use in encoders and the like. Scale patterns such as coils and scale gratings are formed on these scales. This scale pattern is formed by processing a conductor layer on a substrate (for example, Japanese Patent Application Publication No. 2003-166853, Japanese Patent Application Publication No. 2016-44967, Japanese Patent Application Publication No. H10-332360, Japanese Patent Application Publication No. 2008- 126230).

### SUMMARY

In one aspect of the present invention, it is an object of the present invention to provide a method of manufacturing a conductor pattern that can form edges of the conductor pattern with high accuracy while suppressing manufacturing costs.

According to an aspect of the present invention, there is provided a manufacturing method of a conductor pattern including: preparing a substrate provided with a conductor on one main surface thereof; forming an outline of the conductor pattern on the conductor with a short-pulse laser; and removing at least a part of the conductor other than the conductor pattern by etching.

According to another aspect of the present invention, there is provided a manufacturing method of a conductor pattern including: forming a plurality of conductors spaced apart on a substrate; and removing a region other than the conductor pattern from the conductor by a short pulse laser

### BRIEF DESCRIPTION OF DRAWINGS

FIG. 1A illustrates a plan view of a scale;

FIG. 1B illustrates a cross sectional view taken along a line A-A of FIG. 1A;

FIG. 2A to FIG. 2C illustrate a manufacturing method of a scale in accordance with a first embodiment;

FIG. 3A to FIG. 3C illustrate a manufacturing method of a scale in accordance with a second embodiment;

FIG. 4A and FIG. 4B illustrate a manufacturing method of a scale in accordance with a third embodiment;

FIG. 5A to FIG. 5D illustrate a manufacturing method of a scale in accordance with a fourth embodiment;

FIG. 6A illustrates a plan view of a scale; and

FIG. 6B illustrates a cross sectional view taken along a line A-A of FIG. 6A.

### DESCRIPTION OF EMBODIMENTS

It is difficult to form edges of the scale pattern with high accuracy using etching techniques such as those disclosed in Japanese Patent Application Publication No. 2003-166853 and Japanese Patent Application Publication No. 2016-44967. In particular, in a case of a pattern made of a thick-film conductor, it is difficult because the edge taper region spreads also in a height direction. It is difficult to form the edges of the scale pattern with high accuracy even by using the laser processing technique as disclosed in Japanese Patent Application Publication No. H10-332360. Using a short-pulse laser such as that disclosed in Japanese Patent Application Publication No, 2008-126230 makes it possible to form the edges of the scale pattern with high precision, but the processing time is lengthened and the manufacturing cost increases.

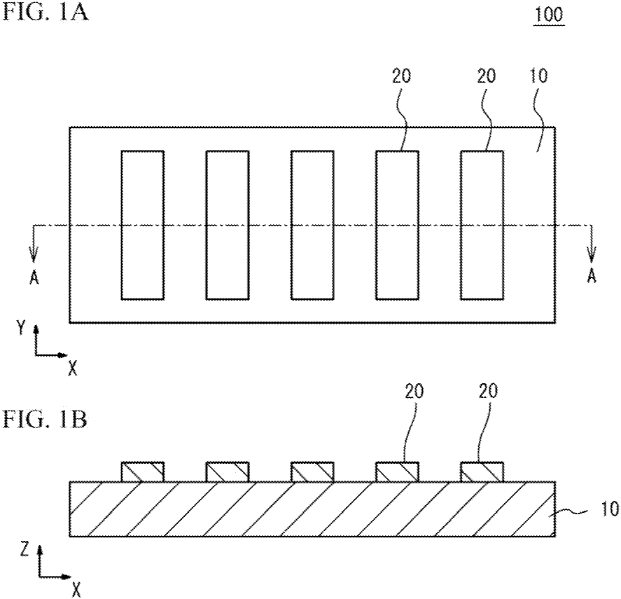

(First embodiment) FIG. 1A is a plan view of a scale 100 manufactured by a manufacturing method according to a first embodiment. FIG. 1B is a sectional view taken along a line A-A of FIG. 1A. The scale 100 is, for example, an electromagnetic induction scale. As illustrated in FIG. 1A and FIG. 1B, the scale 100 has a structure in which a scale pattern 20 (conductor pattern) is arranged on a substrate 10. The scale pattern 20 has a structure in which a plurality of gratings are arranged at predetermined intervals to form a scale gratings. For example, each grating of the scale pattern 20 has a length direction on one main surface of the substrate 10 in a direction orthogonal to the arrangement direction of each grating. The arrangement direction of each grating is defined as the X axis. The stacking direction of the scale pattern 20 with respect to the substrate 10 is defined as the Z-axis. The length direction of each grating and the direction orthogonal to the X-axis and the Z-axis is defined as the Y-axis.

The substrate 10 is made of, for example, prepreg (reinforced plastic molding material), polyimide, glass, CFRP (carbon fiber reinforced plastic), epoxy resin, acrylic resin, urethane resin, polyacetal resin, engineering plastic, stainless steel, invar alloy, aluminum, aluminum alloy, etc.

The scale pattern 20 is formed of a material made of a metal conductor with low resistance such as copper, silver or gold in the case of an electromagnetic induction type. The scale pattern 20 is formed of a material made of a metal conductor with a low resistance such as copper, silver or gold in the case of a photoelectric type, or made of a material that is a highly reflective conductor, such as chromium, titanium, or titanium silicide. The width of each grating of the scale pattern 20 in the X-axis direction is, for example, 2 µm or more and 50 µm or less for L&S in the photoelectric type, and 500 µm or more and 3000 µm or less in the electromagnetic induction type. The thickness of each grating in the Z-axis direction is, for example, 5 µm or more and 30 µm or less in order to obtain a sufficient demagnetizing field response due to high frequencies.

Since the edge position of the scale pattern 20 has the greatest impact on the encoder accuracy, there is a demand for a shape with high processing accuracy that is free from edge tapers and edge roughness that obscure not only the position of the edge portion but also the edge position.

For example, as in Japanese Patent Application Publication No. 2003-166853and Japanese Patent Application Publication No. 2016-44967, in the case of a scale pattern processed through processes such as exposure, development, and etching after forming a resist layer on the surface of a conductor film, processing variations occur at each position on the processing substrate. Therefore, edge roughness increases with each step. In addition, in the etching process, the upper part in the film thickness direction tends to be etched most and the lower part tends to remain, so the taper angle becomes 60 degrees to 70 degrees, and the taper region spreads unevenly to about 2 to 15 µm. Accordingly, the improvement of the processing accuracy of the edge position is suppressed.

In addition, as in Japanese Patent Application Publication No. H10-332360, pattern edges can be processed in a single process for a thick metal by using laser processing. Therefore, the edge roughness becomes small. And irregularly shaped substrates like long substrates of which a mask exposure is difficult can be processed. However, with the conventional laser processing technology, it is difficult to perform precision processing such as edge roughness of 1 µm or less due to the generation of adherents caused by scattering of materials during processing or deformation caused by heat.

Also, as in Japanese Patent Application Publication No, 2008-126230, a conductor pattern with small edge roughness can be obtained by scanning the work surface with a galvanometer scanner or precision stage using a short pulse laser such as a picosecond pulse or femtosecond pulse laser. However, in order to achieve precision, it is necessary to narrow down the laser spot diameter. The processing area per spot becomes finer. Therefore, in order to process the area of the part excluding the conductor that occupies about half the area of the substrate, a long processing time is necessary and the throughput is not improved. Therefore, there is a problem that the manufacturing cost increases. In addition, short-pulse lasers have the problem that the processing rate hits a ceiling and does not increase, because even if the oscillation energy is simply increased, part of the energy is converted into heat. Even if a laser oscillator whose output is large is used, the throughput is not improved.

Therefore, in the present embodiment, a scale manufacturing method capable of forming the edges of the scale pattern with high accuracy while suppressing the manufacturing cost will be described.

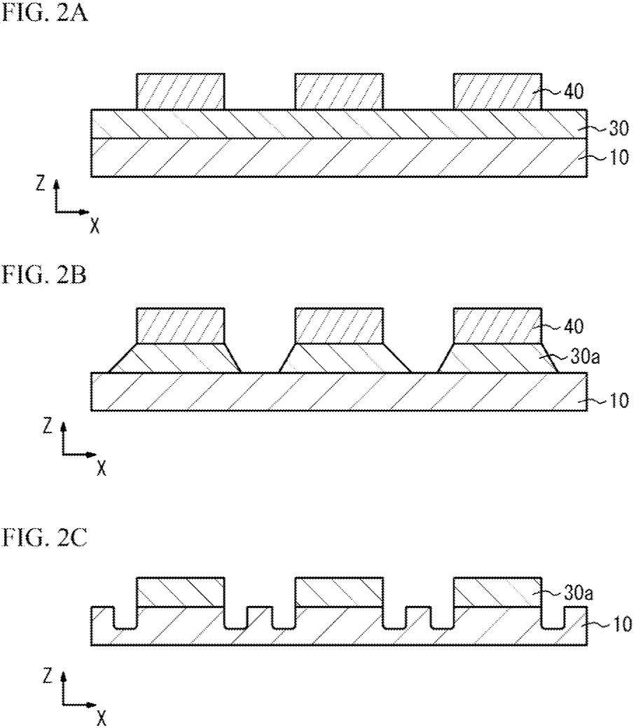

As illustrated in FIG. 2A, the substrate 10 is prepared. On one face of the substrate 10, a conductor layer 30 made of the same material as the scale pattern 20 is formed by foil press molding, plating, or the like. The thickness of the conductor layer 30 is, for example, 5 µm or more and 30 µm or less. After forming a photoresist layer on the conductor layer 30, a resist pattern 40 is formed by photolithography. In this case, the resist pattern 40 is formed so as to be one size larger than each grating of the scale pattern 20 in the X-axis direction, taking into consideration the amount of shaping by laser processing in a later process. For example, the surplus portion of the resist pattern 40 with respect to each grating of the scale pattern 20 is set to approximately 10 µm or more and 20 µm or less at both ends in the X-axis direction. Similar to the scale pattern 20, the resist pattern 40 has a shape in which a plurality of gratings are arranged at predetermined intervals.

Next, as illustrated in FIG. 2B, etching is performed using the resist pattern 40 as a mask. Thereby, the conductor layer 30 is partially removed, and a pattern 30a having substantially the same shape as the resist pattern 40 is formed. Like the scale pattern 20, the pattern 30a has a shape in which a plurality of gratings are arranged at predetermined intervals.

Since the processing accuracy of the etching is not high, each grating portion of the pattern 30a has a substantially trapezoidal shape. For example, in each grating portion of the pattern 30a, edge portions at both ends in the X-axis direction are distributed within a certain range. In this embodiment, the etching accuracy may be low. However, it is required to perform processing with a degree of precision that does not exceed the scope of laser processing. That is, when the etching accuracy is high, the area to be removed in the next laser processing step is reduced. Therefore, the laser processing time can be shortened. Since variation due to edge roughness and positional accuracy is about ±10 µm, a laser processing width of about 20 µm to 30 µm is required.

Next, as illustrated in FIG. 2C, after removing the resist pattern 40, a short pulse laser is used to remove the edge portions of each grating portion of the pattern 30a to obtain a precise edge facet. A short pulse laser can be defined as a laser capable of injecting a pulse with a pulse width on the order of femtoseconds to picoseconds and an energy density of 0.1 to 10 J/cm². As the short pulse laser, for example, a picosecond laser, a femtosecond laser, or the like can be used. By repeatedly irradiating the short-pulse laser at a high speed of 10 kHz to 5 MHz, the inclined portion of the pattern 30a can be removed with high precision along the Z-axis direction. Also, when using the short-pulse laser, the pulse width is shorter than the time (approximately 1 nanosecond) in which light energy is absorbed and converted into heat. Therefore, the laser-irradiated part instantly sublimates without melting. It is possible to suppress material scattering because highly accurate microfabrication which is less likely affected by heat and achieves less damage such as burrs, cracks, and burns can be performed.

According to the manufacturing method according to the present embodiment, since the edges of the grating portions of the pattern 30a are removed by the short pulse laser, the edges of the scale pattern 20 can be formed with high precision. For example, by setting the edge roughness to 1 µm or less, the measurement accuracy using the scale 100 can be set to 1 µm or less. In addition, since the short-pulse laser is used after the conductor pattern is formed with low accuracy by etching, the processing time can be shortened as compared with the case where only the short-pulse laser with a small spot diameter is used for processing. Thereby, the manufacturing cost can be suppressed. As described above, the edge of the scale pattern can be formed with high accuracy while suppressing the manufacturing cost. In addition, the influence of temperature drift can be reduced by shortening the processing time using the short-pulse laser. In addition, since etching processing accuracy may be low, there is no need to use an expensive high-precision lithography apparatus.

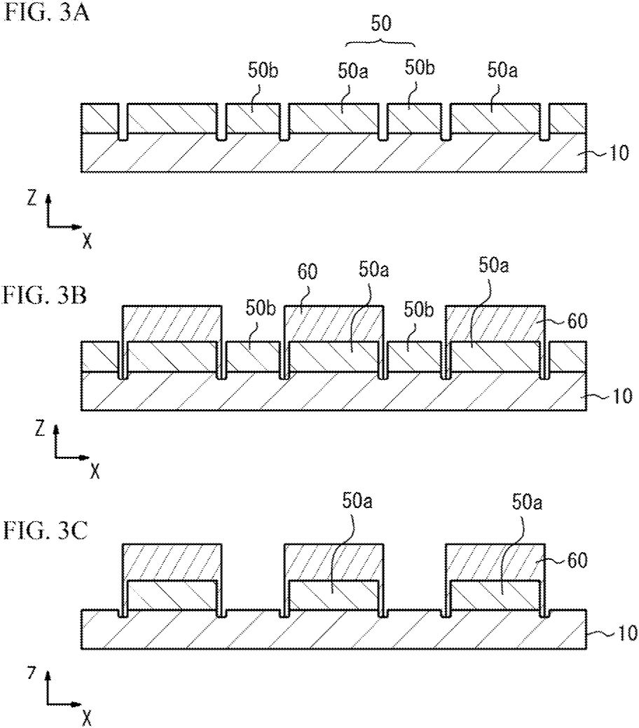

(Second embodiment) As illustrated in FIG. 3A, the substrate 10 is prepared. One face of the substrate 10, a conductor layer 50 made of the same material as the scale pattern 20 is deposited by foil press molding, plating, or the like. The thickness of the conductor layer 50 is, for example, 5 µm or more and 30 µm or less. A contour having the same shape as the scale pattern 20 is formed by partially removing the conductor layer 50 using a short-pulse laser to form laser-processed grooves. In this case, from the conductor layer 50, patterns 50a corresponding to the scale patterns 20 and remaining portions 50b between the patterns 50a are formed. The spot diameter of the short-pulse laser capable of fine processing is, for example, 3 µm or more and 10 µm or less. The outline should be processed with the same width as the spot diameter. Therefore, the width of the laser-processed groove can also be 3 µm or more and 10 µm or less. In order to process a uniform film, the laser processing conditions are the same at all locations, and edge patterns of uniform quality can be obtained.

Next, as illustrated in FIG. 3B, after forming a photoresist layer so as to cover the pattern 50a and the remaining portion 50b, a resist pattern 60 is formed by photolithography. In this case, the resist pattern 60 is formed so as to be one size larger than each grating of the scale pattern 20 in the X-axis direction, taking into consideration the amount of shaping by laser processing in a later process. However, the resist pattern 60 should not remain on the surface of the remaining portion 50b. For example, the end face of the resist pattern 60 is positioned near the center of the laser-processed groove portion in the X-axis direction.

Next, as illustrated in FIG. 3C, the remaining portion 50b is removed by etching using the resist pattern 60 as a mask. Since the etching is performed while the pattern 50a formed with high accuracy is protected by the resist pattern 60, the etching time is less restricted and the etching can be easily performed without defects.

According to the manufacturing method according to this embodiment, since the laser-processed grooves are formed in the conductor layer 50 by the short-pulse laser, the pattern 50a can be formed with high accuracy. For example, by setting the edge roughness to 1 µm or less, the measurement accuracy using the scale 100 can be set to 1 µm or less. In addition, since the remaining portion 50b is removed by etching, the processing time can be shortened compared to the case of processing only with a short-pulse laser with a small spot diameter. Thereby, the manufacturing cost can be suppressed. As described above, the edge of the scale pattern 20 can be formed with high accuracy while suppressing the manufacturing cost. In addition, the influence of temperature drift can be reduced by shortening the processing time using the short-pulse laser.

In addition, with this method, the area to be processed by laser can be minimized, and variations in processing accuracy are also reduced. In addition, poor wet etching processing is less likely to occur. Moreover, if the resist is a permanent resist, it is possible to protect the end face of the conductor pattern that has been precisely processed as a protective film, so that it is possible to reduce the number of processes. Therefore, productivity is higher than in the first embodiment, and fine scale patterns can be processed.

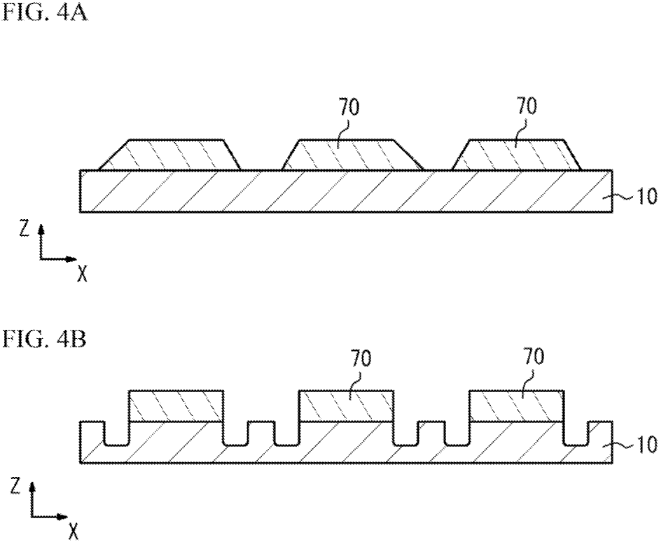

(Third embodiment) As illustrated in FIG. 4A, on one main surface of the substrate 10, a conductive paste containing the same material as the scale pattern 20 is used as an ink and printed by a printing method such as screen printing, inkjet printing, or offset printing. A conductor 70 is formed by filming and firing, stamp plating, or the like from the conductive paste. The thickness of the conductor 70 is, for example, 5 µm or more and 30 µm or less. The conductor 70 is formed to be one size larger than each grating of the scale pattern 20 in the X-axis direction. Like the scale pattern 20, the conductor 70 has a shape in which a plurality of gratings are arranged at predetermined intervals. Since the ink spreads smoothly, each grating portion of the conductor 70 has a substantially trapezoidal shape. For example, in each grating portion of the conductor 70, edge portions at both ends in the X-axis direction have inclined portions that are inclined with respect to the Z-axis direction.

Next, as illustrated in FIG. 4B, the edge portions of each grating portion of the conductor 70 are removed by a short pulse laser in accordance with the end face position of each grating of the scale pattern 20. This allows the scale pattern 20 to be obtained from the conductor 70 .

According to the manufacturing method according to the present embodiment, since the edge portions of the grating portions of the conductor 70 are removed by the short pulse laser, the edges of the scale pattern 20 can be formed with high accuracy. For example, by setting the edge roughness to 1 µm or less, the measurement accuracy using the scale 100 can be set to 1 µm or less. Further, since the short-pulse laser is used after the conductor 70 is formed with low accuracy, the processing time can be shortened as compared with the case where only the short-pulse laser with a small spot diameter is used for processing. Thereby, the manufacturing cost can be suppressed. As described above, the edge of the scale pattern 20 can be formed with high accuracy while suppressing the manufacturing cost. In addition, the influence of temperature drift can be reduced by shortening the processing time using the short-pulse laser.

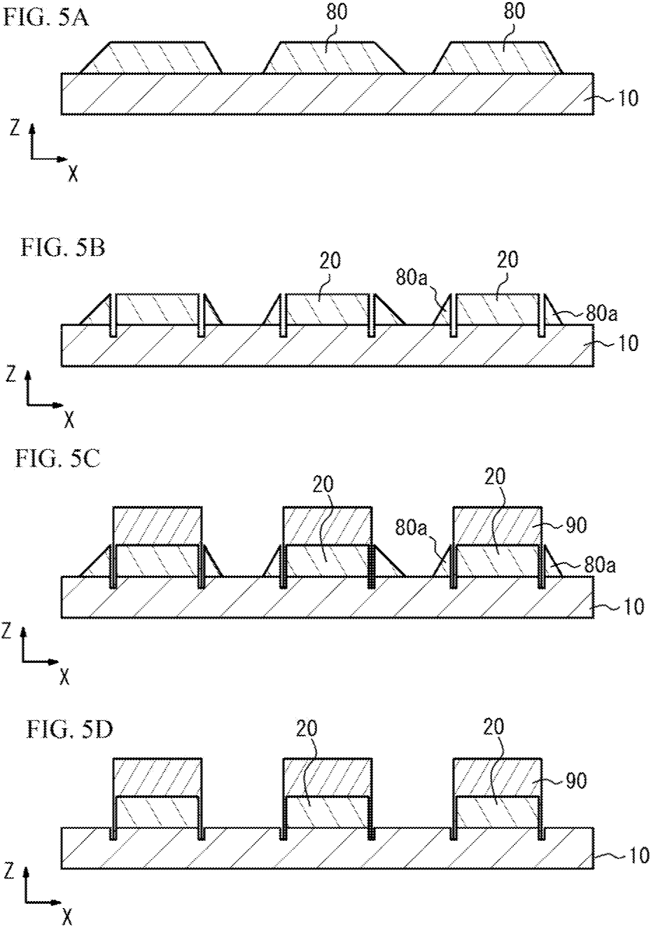

(Fourth embodiment) As illustrated in FIG. 5A, on one main surface of the substrate 10, a conductor 80 is formed by printing and firing, stamp plating, or the like. In the printing, a conductive paste containing the same material as the scale pattern 20 is used as an ink and printed by a printing method such as screen printing, inkjet printing, or offset printing. The thickness of the conductor 80 is, for example, 5 µm or more and 30 µm or less. The conductor 80 is formed to be one size larger than each grating of the scale pattern 20 in the X-axis direction. Like the scale pattern 20, the conductor 80 has a shape in which a plurality of gratings are arranged at predetermined intervals. Since the ink spreads smoothly, each grating portion of the conductor 80 has a substantially trapezoidal shape. For example, in each grating portion of the conductor 80, edge portions at both ends in the X-axis direction have inclined portions that are inclined with respect to the Z-axis direction.

Next, as illustrated in FIG. 5B, the conductor 80 is partially removed using a short pulse laser to form a laser-processed groove, thereby forming a contour having the same shape as the scale pattern 20. In this case, the scale pattern 20 and a remaining portion 80a are formed from the conductor 80. A spot diameter of the short-pulse laser capable of fine processing is about 3 µm to 10 µm. The outline should be machined with the same width as the spot diameter. In order to process a uniform film, the laser processing conditions are the same at all locations, and edge patterns of uniform quality can be obtained.

Next, as illustrated in FIG. 5C, after forming a photoresist layer so as to cover the scale pattern 20 and the remaining portion 80a, a resist pattern 90 is formed by photolithography. In this case, the resist pattern 90 is formed so as to be one size larger than each grating of the scale pattern 20 in the X-axis direction, taking into consideration the amount of shaping by laser processing in a later process. However, the resist pattern 90 should not remain on the surface of the remaining portion 80a. For example, the end surface of the resist pattern 90 is positioned near the center of the laser-processed groove portion in the X-axis direction.

Next, as illustrated in FIG. 5D, the remaining portion 80a is removed by etching using the resist pattern 90 as a mask. Since the etching is performed while the scale pattern 20 formed with high accuracy is protected by the resist pattern 90, the etching time is less restricted and the etching can be easily performed without defects.

According to the manufacturing method according to the present embodiment, since the laser-processed grooves are formed in the conductor 80 by the short-pulse laser, the edges of the scale pattern can be formed with high accuracy. For example, by setting the edge roughness to 1 µm or less, the measurement accuracy using the scale 100 can be set to 1 µm or less. In addition, since the remaining portion 80a is removed by etching, the processing time can be shortened compared to the case of processing only with a short-pulse laser with a small spot diameter. Thereby, the manufacturing cost can be suppressed. From the above, it is possible to improve the processing accuracy while suppressing the cost. In addition, the influence of temperature drift can be reduced by shortening the processing time using the short-pulse laser.

In addition, with this method, the area to be processed by laser can be minimized, and variations in processing accuracy are also reduced. In addition, poor wet etching processing is less likely to occur. Moreover, if the resist is a permanent resist, it is possible to protect the end face of the conductor pattern that has been precisely processed as a protective film, so that it is possible to reduce the number of processes. Therefore, productivity is higher than in the first embodiment, and fine scale patterns can be processed.

In each of the above embodiments, the scale pattern has a structure in which a plurality of grating shapes are arranged, but the structure is not limited to this. For example, each of the above embodiments can be applied to a scale pattern in which a plurality of coils are arranged at predetermined intervals in the X-axis direction.

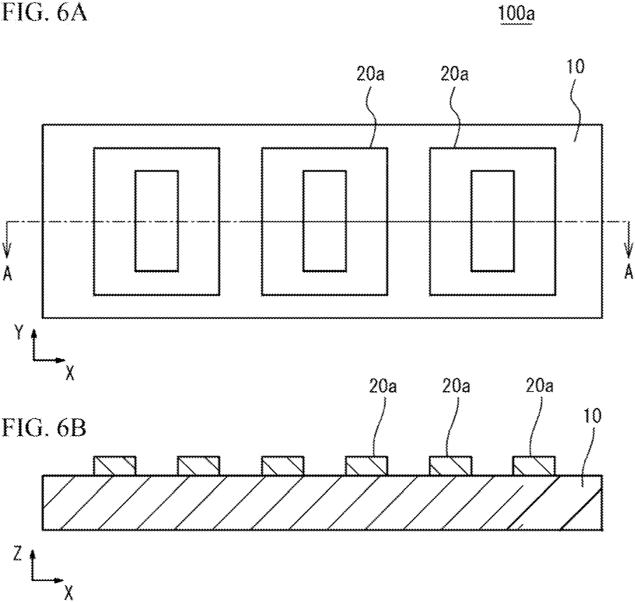

FIG. 6A is a plan view of a scale 100a having a scale pattern 20a in which a plurality of coils are arranged in the X-axis direction at predetermined intervals. FIG. 6B is a cross-sectional view taken along line AA of FIG. 6A. As illustrated in FIG. 6A and FIG. 6B, the scale 100a has a structure in which the scale pattern 20a is arranged on the substrate 10. The scale pattern 20a has a structure in which a plurality of coils are arranged at predetermined intervals. The arrangement direction of each coil is defined as the X axis.

If the manufacturing method of the first embodiment is applied to the scale 100a, the processing time can be reduced to 1/20 compared to the case where all the punched pattern portions are laser processed. This is because, if the L&S of the coil pattern is about 1000 µm/ 1000 µm, the total width of both ends of the pattern is about 50 µm.

When the manufacturing method of the second embodiment is applied to the scale 100a, the processing time can be reduced to 1/100. This is because, when a laser with a spot diameter of 5 µm is used, if L&S is 1000 µm/ 1000 µm, the total width of both ends is 10 µm.

If the manufacturing method of the third embodiment is applied to the scale 100a, the processing time can be reduced to ⅒ compared to the case where all the punched pattern portions are laser processed. This is because if L&S of the coil pattern is 1000 µm/ 1000 µm, the total width of both ends is 50 µm.

If the manufacturing method of the fourth embodiment is applied to the scale 100a, the processing time can be reduced to 1/100 compared to the case where all the punched pattern portions are laser processed. This is because if the L&S of the coil pattern is about 1000 µm/ 1000 µm, the total width of both ends of the pattern is about 10 µm.

Although each of the above embodiments is applied to an electromagnetic induction scale, it may be applied to other scales. For example, the above embodiments can be applied to a conductive pattern included in indicators, micrometers, vernier calipers, height gauges, linear encoders, rotary encoders, antenna patterns formed on glass substrates and spindle parts that provide temperature stability, ultra-high precision sensors, glass MEMS sensors, or the like.

The present invention is not limited to the specifically disclosed embodiments and variations but may include other embodiments and variations without departing from the scope of the present invention.

What is claimed is:

1. A manufacturing method of a conductor pattern comprising:
preparing a substrate provided with a conductor on one main surface thereof;
forming an outline of the conductor pattern on the conductor with a short-pulse laser; and
removing at least a part of the conductor other than the conductor pattern by etching.

2. The method as claimed in claim 1,
wherein, after forming a resist pattern on the conductor by photolithography, etching is performed using the resist pattern as a mask, and then the outline of the conductor pattern is formed by the short pulse laser.

3. The method as claimed in claim 1,
wherein, after forming the outline of the conductor pattern on the conductor with the short pulse laser, a resist pattern is formed so as to cover the conductor pattern, and then the conductor not covered with the resist pattern is removed by etching.

4. The method as claimed in claim 1, further comprising:
forming a plurality of the conductor spaced apart from each other, on the substrate so as to array,
wherein, after forming the outline of the conductor pattern on the conductor with the short pulse laser, a resist pattern is formed so as to cover the conductor pattern, and then the conductor not covered with the resist pattern is removed by etching.

5. A manufacturing method of a conductor pattern comprising:
forming a plurality of conductors spaced apart on a substrate; and
removing a region other than the conductor pattern from the conductor by a short pulse laser.

6. The method as claimed in claim 5,
wherein the conductor is formed on the substrate by printing or stamp plating.

7. The method as claimed in claim 1, wherein a width of a laser-processed groove formed by the short-pulse laser is 3 µm or more and 100 µm or less.
